(19) United States
(12) Patent Application Publication
(10) Pub. No.: US 2008/0048795 A1
(43) Pub. Date: Feb. 28, 2008

(54) VOLTAGE CONTROLLED OSCILLATOR, BIAS DEVICE FOR VOLTAGE CONTROLLED OSCILLATOR, BIAS ADJUSTMENT PROGRAM FOR VOLTAGE CONTROL OSCILLATOR

(75) Inventors: Hiroaki Hoshino, Yokohama-shi (JP); Shoji Ootaka, Yokohama-shi (JP); Ryoichi Tachibana, Kawasaki-shi (JP)

Correspondence Address: AMIN, TUROCY & CALVIN, LLP, 1900 EAST 9TH STREET, NATIONAL CITY CENTER, 24TH FLOOR,, CLEVELAND, OH, 44114, US

(73) Assignee: KABUSHIKI KAISHA TOSHIBA, Tokyo (JP)

(21) Appl. No.: 11/840,379

(22) Filed: Aug. 17, 2007

(30) Foreign Application Priority Data
Aug. 22, 2006 (JP) 2006-224989

(51) Int. Cl. H03L 5/00

(52) U.S. Cl. 331/183; 331/109

(57) ABSTRACT

Disclosed is a voltage controlled oscillator including: a first element and a second element each passing a current therethrough varying based on a controlled signal; an oscillation circuit configured to generate an oscillation wave in each of a first state in which the current through the first element is current-inputted and a second state in which the current through the second element is current-inputted; a switching circuit switching between the first state and the second state; a current estimation circuit configured to estimate the current through the first element in the first state and to generate an estimation result; and a control circuit configured to generate the control signal for the second element so as to designate a current according to the estimation result as the current through the second element in the second state.

### CROSS-REFERENCE TO RELATED APPLICATION

This application is based upon and claims the benefit of priority from the prior Japanese Patent Application No. 2006-224989, filed on Aug. 22, 2006; the entire contents of which are incorporated herein by reference.

### BACKGROUND OF THE INVENTION

1. Field of the Invention

The present invention relates to a voltage controlled oscillator, a bias device for a voltage controlled oscillator and a bias adjustment program preferable for mobile telephones for example.

2. Description of the Related Art

In a radio communication technique used in a mobile telephone or the like for example, there are required a function to convert a base band signal to a higher frequency for transmitting the signal via an antenna, and a function to convert a high frequency signal received by the antenna into a base band signal. For these functions, a frequency converter and a local oscillator are used.

Generally, the local oscillator is controlled so that an oscillation frequency in a voltage controlled oscillator as a component thereof becomes a constant multiple of a reference oscillation frequency provided by a crystal or the like. Thus, a frequency needed for communication is set. Here, it is required for the voltage controlled oscillator to oscillate within a predetermined frequency range, to have a predetermined high C/N characteristic, and soon. As an index for the high C/N characteristic, generally, phase noise representing a ratio of noise power in a frequency, which is different from the oscillation frequency by a predetermined frequency, to oscillation power is used. To reduce the phase noise, the noise power needs to be suppressed or the oscillation power needs to be increased.

In the voltage controlled oscillator, the noise power and the oscillation power are varied by a bias provided thereto, and there exists an optimum bias which minimizes the phase noise. Accordingly, contrivances have been made for providing such a bias. Further, there has been performed bias control so as to make the waveform amplitude of an oscillation output signal, which is relevant to the magnitude of phase noise, to be a predetermined magnitude.

As a technique to control the bias, there is a configuration to automatically control a bias using a transistor as a bias current source (for example, refer to U.S. Pat. No. 6,838,952). In this configuration, first the output signal amplitude of the voltage controlled oscillator is detected by a detection circuit. Then, a detection signal thereof is compared with a reference signal, and a voltage corresponding to the difference thereof is provided to the transistor operating as the current source, thereby obtaining an optimum bias by a feedback loop. Specifically, using the fact that the output amplitude depends on a bias current in the voltage controlled oscillator, reduction of the phase noise is attempted indirectly by controlling the output amplitude. This configuration is characterized in that a variable current source using a transistor is used to vary the bias voltage continuously.

Further, as a configuration different from this, there is proposed a configuration to perform the control of a bias current in the voltage controlled oscillator with switches and resistors (for example, refer to “John W. M. Rogers, et al., “A Study of Digital and Analog Automatic-Amplitude Control Circuitry for Voltage-Controlled Oscillators”, IEEE JOURNAL OF SOLID-STATE CIRCUITS, IEEE, Vol. 38, No. 2, pp. 352-356, February 2003”). In this configuration, to obtain a predetermined output amplitude, by comparing the output amplitude with a predetermined amplitude for a predetermined time after a switch is switched, it is decided whether to further perform switching of the switch for increasing the current or to keep the current as it is.

In these configurations, the former one has a possibility that the phase noise of an output signal increases by noise generated by the transistor as the current source. Further, the latter one takes time until obtaining an optimum bias because the amplitude comparison must be repeated for every switching.

### BRIEF SUMMARY OF THE INVENTION

A voltage controlled oscillator according to one aspect of the present invention includes: a first element and a second element each having a passing current therein varying based on a control signal; an oscillation circuit configured to generate an oscillation wave in each of a first state in which the passing current in the first element is inputted as a current and a second state in which the passing current in the second element is inputted as a current; a switching circuit switching between the first state and the second state; a current estimation circuit configured to estimate the passing current in the first element in the first state and to generate an estimation result; and a control circuit configured to generate the control signal for the second element so as to designate a current according to the estimation result as the passing current in the second element in the second state.

Further, a bias device according to another aspect of the present invention includes: a current estimation circuit configured to estimate, for an oscillation circuit which generates an oscillation wave in a state that a current passing through a first element is inputted, the current passing through the first element and to generate an estimation result; and a control circuit configured to control a second element, when an oscillation wave is generated in a state that a current passing through the second element instead of the first element is inputted to the oscillation circuit, so as to designate a current according to the estimation result as the current passing through the second element.

Further, a bias adjustment program for a voltage-controlled oscillator according to still another aspect of the present invention includes instructions to cause a processor to execute: counting an elapsed time from an instant of generation of a frequency switching signal; monitoring changes of a bias current in a voltage controlled oscillator equivalently while the elapsed time is counted; determining whether or not changes of the bias current per predetermined time fall within a predetermined range based on the counting; and outputting to the voltage controlled oscillator a signal for switching an element which adjusts the bias current when the changes of the bias current per the predetermined time fall within the predetermined range.

Further, a bias adjustment program for a voltage controlled oscillator according to yet another aspect of the present invention includes instructions to cause a processor to execute: counting of an elapsed time from an instant of generation of a frequency switching signal; and outputting to a voltage controlled oscillator a signal for switching an element which adjusts a bias current when the elapsed time reaches a predetermined time.

### BRIEF DESCRIPTION OF THE SEVERAL VIEWS OF THE DRAWINGS

FIG. 1 is a block diagram showing a configuration of a voltage controlled oscillator according to one embodiment.

FIG. 2 is a block diagram showing the voltage controlled oscillator shown in FIG. 1 as a more concrete configuration example.

FIG. 3 is a circuit block diagram showing the voltage controlled oscillator shown in FIG. 2 as a further concrete configuration example.

FIG. 4 is a circuit diagram showing a concrete example of an amplitude detection circuit 15 shown in FIG. 1 to FIG. 3.

FIG. 5 is a circuit diagram showing a concrete example of generating a reference voltage Vref shown in FIG. 1 to FIG. 3.

FIG. 6A, FIG. 6B are a functional block diagram (FIG. 6A) showing a control system example generating a switching signal and a strobe signal shown in FIG. 2 and FIG. 3 and a processing flowchart thereof (FIG. 6B), respectively.

FIG. 7 is a graph showing in a time-related manner an example of a state of frequency switching in the voltage controlled oscillator realized by the voltage controlled oscillator shown in FIG. 3 and the system shown in FIG. 6A, FIG. 6B.

FIG. 8A, FIG. 8B are a functional block diagram (FIG. 8A) showing another control system example generating the switching signal and the strobe signal shown in FIG. 2 and FIG. 3, and a flowchart (FIG. 8B) showing the flow of processing thereof.

FIG. 9 is a circuit block diagram showing the voltage-controlled oscillator shown in FIG. 2 as another concrete configuration example.

### DETAILED DESCRIPTION OF THE INVENTION

### Explanation of Embodiments

Embodiments of the present invention will be described with reference to the drawings, but these drawings are provided only for illustrative purposes, and by any means not limiting the present invention.

A voltage controlled oscillator according to one mode has an oscillation circuit capable of oscillating in a first state in which a bias current is adjusted by a first element, and a second state in which the bias current is adjusted by a second element, and characteristics in these respective states can be utilized. In the first state, quick transition to a phase noise reduced state is possible for example. In the second state, the oscillation circuit is controlled so that the bias current in the first state is maintained. Here, when the second element is a low noise element, the phase noise is reduced further.

A bias device as another mode is a device to control the second element by supplying a bias to the second element which is provided in the voltage controlled oscillator. In a state that a bias current in the voltage controlled oscillator is adjusted by the first element present in the voltage controlled oscillator, the bias current is estimated as a first current, and the second element is controlled so that a second current corresponding to the first current is allowed to flow via the second element as the bias current in the voltage controlled oscillator. In a state that the bias current is allowed to flow by the first element in the voltage controlled oscillator, quick transition to a phase noise reduced state is possible for example. When the bias current is allowed to flow by the second element in the voltage controlled oscillator, the second element is controlled so that the bias current in the state that the bias current is allowed to flow by the first element is maintained. Here, when the second element is a low noise element, the phase noise is reduced further.

A program as still another mode is for outputting to the voltage controlled oscillator a transition signal for transition from a bias current adjusted state by a certain element to a bias current adjusted state by another element. In the voltage controlled oscillator, in the bias current adjusted state by the one element, quick transition to the phase noise reduced state is performed for example. Completion of the transition is determined from substantial convergence of changes of the bias current. In the bias current adjusted state by the other element, the phase noise is further reduced when the element is a low noise element.

A program as yet another mode is also for outputting to the voltage controlled oscillator a transition signal for transition from a bias current adjusted state by a certain element to a bias current adjusted state by another element. In the voltage controlled oscillator, in the bias current adjusted state by the one element, quick transition to the phase noise reduced state is performed for example. Completion of the transition is determined by elapse of a time which is determined in advance. In the bias current adjusted state by the other element, the phase noise is further reduced when the element is a low noise element.

A form in the above-described one mode can be configured such that there are further provided an amplitude detecting circuit which detects an oscillation amplitude of the oscillation circuit in the first state, and a comparison and amplification circuit which supplies an output of comparing the oscillation amplitude with a predetermined value and amplifying it to the first element as a control signal to control the first element, the oscillation amplitude and the phase noise vary depending on the bias current in the oscillation circuit, and the current estimation circuit estimates the first current by being inputted the control signal.

Focusing on the fact that the oscillation amplitude of the oscillation circuit has relevance to the phase noise, this form is arranged for controlling the oscillation amplitude to a predetermined magnitude in the first state. The control signal to control the first element is used for estimating the first current in the current estimation circuit.

Further, a form can be configured such that the first element is a transistor, and the control signal is supplied to the gate terminal or the base terminal of the transistor. This is a concrete example of the first element. When the first element is constituted of a transistor, the control signal can be an analog signal, and thereby it is possible to avoid taking time for convergence in the case where the control signal is to be an opening/closing signal for a plurality of switches.

Further, a form can be configured such that the second element has a circuit in which a plurality of serial connections of resistors and switches are connected in parallel, and the control circuit controls the second element by defining opening/closing states of the switches. This is a concrete example of the second element and also an example of connecting the second element and the control circuit. When the second element is constituted of a resistor and a switch, the phase noise of the oscillation circuit during a regular state can be reduced more than in the case of the transistor.

Here, a form can be configured such that the current estimation circuit has a plurality of current comparison circuits which compare the bias current in the first state with each of a plurality of current values which differ stepwise from each other and output a plurality of comparison results as the estimation result of the first current, the control circuit has a latch circuit storing the plurality of comparison results, and an output of the latch circuit is supplied to the second element to define opening/closing states of the respective switches. This is an example of a circuit for defining opening/closing states of switches of the second element. Since the opening/closing states of switches are fixed by the latch circuit, the bias current in the oscillation circuit is fixed.

Further, a form can be configured such that the first element is a transistor, the control signal is supplied to a gate terminal or a base terminal of the transistor, the second element has a circuit in which a plurality of serial connections of resistors and switches are connected in parallel, the current estimation circuit has a plurality of transistors constituting current mirror circuits respectively with the transistor as the first element and a plurality of current comparison circuits which compare currents flowing in the plurality of transistors with each of a plurality of current values which differ stepwise from each other and output a plurality of comparison results as the estimation result of the first current, the control circuit has a latch circuit storing the plurality of comparison results, and an output of the latch circuit is supplied to the second element and defines opening/closing states of each of the switches so as to control the second element.

In this form, the current estimation circuit in particular is provided with a plurality of transistors constituting current mirror circuits respectively with the transistor as the first element. With such a configuration, currents corresponding to a bias current in the oscillator can be easily generated for the respective transistors. Therefore, comparison with a plurality of current values which differ stepwise from each other can be easily realized.

Here, a form can be configured such that gate widths or emitter sizes are differentiated from each other so that a current scale is differentiated between the transistor as the first element and the plurality of transistors constituting current mirror circuits respectively with the transistor. Thereby, a consumed current in the current estimation circuit can be reduced significantly. A power saving configuration can be obtained.

Furthermore, a form can be configured such that the current comparison circuit has a plurality of resistors having resistance values which differ stepwise from each other, and the plurality of current values of the current comparison circuit are generated as respective currents flowing through the plurality of resistors. This form is for generating current values by difference in resistance values, as reference for comparing currents.

Moreover, a form can be configured such that the current comparison circuit has a plurality of transistors having gate widths or emitters of sizes which differ stepwise from each other, and the plurality of current values in the current comparison circuit are generated as currents flowing through the plurality of transistors having the gate widths or emitters of the sizes, respectively. This form is for generating current values by difference in sizes of the gate widths or emitters, as reference for comparing currents.

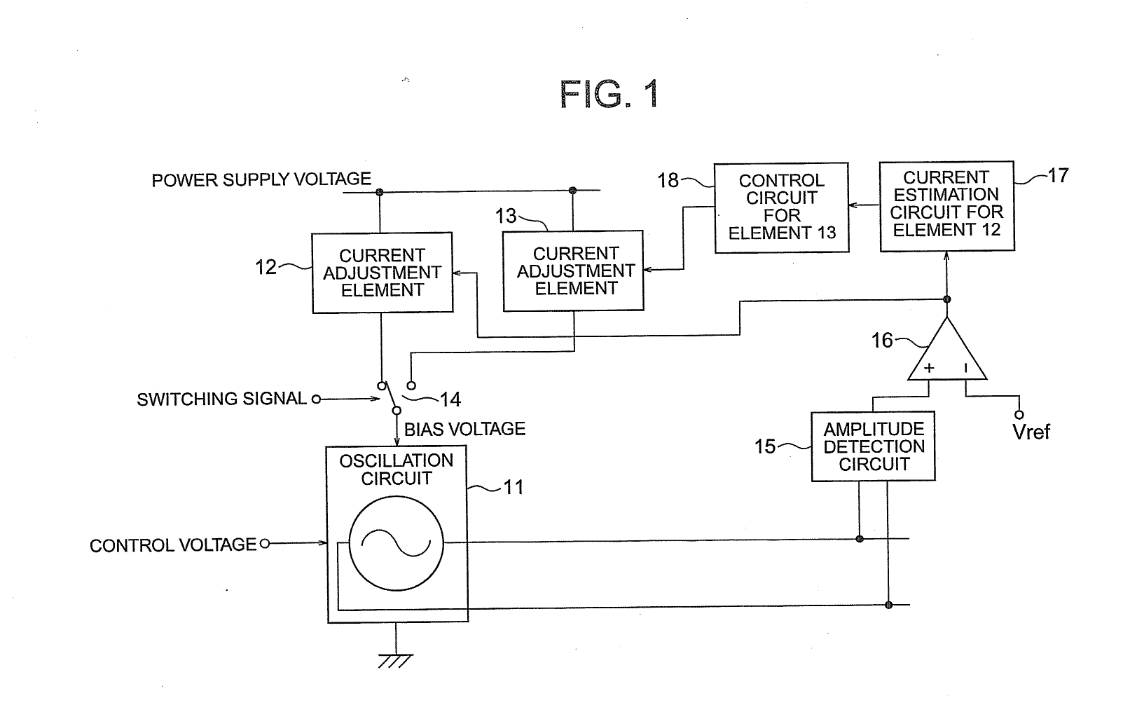

Based on the above, embodiments will be described below with reference to the drawings. FIG. 1 shows a configuration of a voltage controlled oscillator according to one embodiment. As shown in FIG. 1, this voltage controlled oscillator has an oscillation circuit 11, current adjustment elements 12, 13, a switch 14, an amplitude detection circuit 15, a comparison and amplification circuit 16, a current estimation circuit 17, and a control circuit 18.

The oscillation circuit 11 oscillates by a bias current flowing therethrough. The bias current is switched between a state of adjustment by the current adjustment element 12 and a state of adjustment by the current adjustment element 13 by a switching position in the switch 14 as a switching circuit. Further, the oscillation circuit 11 has an input terminal for a control voltage as the voltage controlled oscillator. The control voltage controls the oscillation frequency. Oscillation outputs of both phases of the oscillation circuit 11 may be supplied to respective parts which need them. Further, in this voltage controlled oscillator, the oscillation outputs are also supplied to the amplitude detection circuit 15.

Note that in this oscillation circuit 11, the magnitude of an oscillation amplitude and the magnitude of phase noise vary depending on the magnitude of the bias current. Here, when the oscillation amplitude is a predetermined magnitude, the phase noise is minimized. Further, it is arranged such that the center frequency of oscillation is varied by a not-shown control input. This control input performs switching of the band of the oscillation frequency. The oscillation amplitude also varies by switching the band of the oscillation frequency.

The current adjustment element 12 is an element capable of adjusting a current passing therethrough (current passing from the power supply voltage side to the side of the switch 14) by external control, and an output of the comparison and amplification circuit 16 performs this control. The current adjustment element 13 is similarly an element capable of adjusting a current passing therethrough (current passing from the power supply voltage side to the side of the switch 14) by external control, and the control circuit 18 performs this control. The switch 14 performs switching regarding whether the bias current in the oscillation circuit 11 is the current from the current adjustment element 12 or the current from the current adjustment element 13.

An oscillation output of the oscillation circuit 11 is led to the amplitude detection circuit 15, and thereby detection of the oscillation amplitude of the oscillation circuit 11 is performed. An output obtained by the detection is supplied to the comparison and amplification circuit 16 as one input thereof. Taking the output of the amplitude detection circuit 15 as a comparison subject, the comparison and amplification circuit 16 compares it with a predetermined value (reference voltage Vref) as a comparison reference in an analog manner, and amplifies a comparison result thereof with a large gain. An output obtained by the amplification is supplied to the current adjustment element 12 as a signal to control this element, and also led to the current estimation circuit 17.

An output of the comparison and amplification circuit 16 is led to the current estimation circuit 17, and thereby in a state (first state) in which the bias current is allowed to flow from the current adjustment element 12 to the oscillation circuit 11 by switching of the switch 14, estimation of the value of the current is performed. The result of the estimation is led to the control circuit 18. The control circuit 18 controls the current adjustment circuit 13 according to the result of the comparison led thereto. Specifically, the control circuit 18 controls the current adjustment element 13 so that a current in a state (second state) that the bias current is allowed to flow from the current adjustment element 13 to the oscillation circuit 11 by switching of the switch 14 becomes equal to the current allowed to flow in the current adjustment element 12 in the first state.

In the configuration as above, by selectively using the types of specific elements of the current adjustment element 12 and the current adjustment element 13, the degree of phase noise originated in the current adjustment element 13 can be made smaller than phase noise originated in the current adjustment element 12 in the oscillation circuit 11. Therefore, in a regular state (normal oscillation state), the switching position of the switch 14 is set to a position that enables the current adjustment element 13 to allow the bias current flowing to the oscillation circuit 11. Accordingly, the phase noise in the regular state can be suppressed.

This state of suppressing the phase noise is realized only if the current in the current adjustment element 12 (namely the bias current in the first state) is estimated by the current estimation circuit 17, and then the control circuit 18 controls the current adjustment element 13 by the result of this estimation. Accordingly, when the band of the oscillation frequency of the oscillation circuit 11 is switched, the switch 14 is switched to the side of the current adjustment element 12 temporarily, thereby creating a state that the current adjustment element 12 leads the bias current to the oscillation circuit 11. In this state, the current in the current adjustment element 12 is estimated by the current estimation circuit 17.

In a state that the switch 14 is switched to the side of the current adjustment element 12, the adjustment of the current by the current adjustment element 12 is carried out in a feedback loop of the oscillation circuit 11, the amplitude detection circuit 15, the comparison and amplification circuit 16, and the current adjustment element 12. In a state that this feedback loop is formed, the detection result from the amplitude detection circuit 15 converges to a value according to Vref. In addition, variations in the output voltage of the comparison and amplification circuit 16 and the current in the current adjustment element 12 also converge. Here, the speed of this convergence is much faster than by digitally controlling the current adjustment element 12 to adjust the current therein for example because the convergence is in an analog manner by means of feedback.

Note that since this convergence occurs in such a manner that the result of detection from the amplitude detection circuit 15 becomes equal to a value according to Vref, Vref may be determined in advance corresponding to an oscillation amplitude which minimizes the phase noise from the oscillation circuit 11. Further, since the output of the comparison and amplification circuit 16 at the time of convergence is inputted to the input of the current estimation circuit 17, the control circuit 18 stores the estimation result by the current estimation circuit 17 at that time.

As a complement about the feedback loop having a path of the oscillation circuit 11, the amplitude detection circuit 15, the comparison and amplification circuit 16, and the current adjustment element 12, an input polarity to the comparison and amplification circuit 16 is selected so that the loop becomes negative feedback. In this embodiment, the characteristic of control voltage→current of the current adjustment element 12 is negative, the characteristic of bias current→oscillation amplitude of the oscillation circuit 11 is positive, and the characteristic of the input→output of the amplitude detection circuit is positive. Therefore, the output of the amplitude detection circuit 15 is supplied as a non-inverted input of the comparison and amplification circuit 16.

The temporary switching state of the switch 14 to the side of the current adjustment element 12 is finished by storing of the comparison result by the control circuit 18, and thereafter the switch 14 is switched to the side of the current adjustment element 13 as in an original state. Thereafter, the current adjustment element 13 is controlled by the control circuit 18. Since this control is neither done by the feedback loop nor done accompanying sequential comparison or convergence in an analog manner, an appropriately controlled state is realized instantaneously. Specifically, the phase noise is reduced in terms of the oscillation amplitude, and also it is a state that the phase noise is reduced in terms of the current adjustment element used.

With the operation as described above, the switching operation at the time of band switching is quick, in other words, transition to the state that the phase noise is suppressed is made quick. Such an effect cannot be obtained in a configuration having only analog feedback because of the disadvantage of an amount of phase noise originated in the current adjustment element 12, and also cannot be obtained in a configuration of sequential comparison that takes quite a few steps to decide the control signal for the current adjustment circuit.

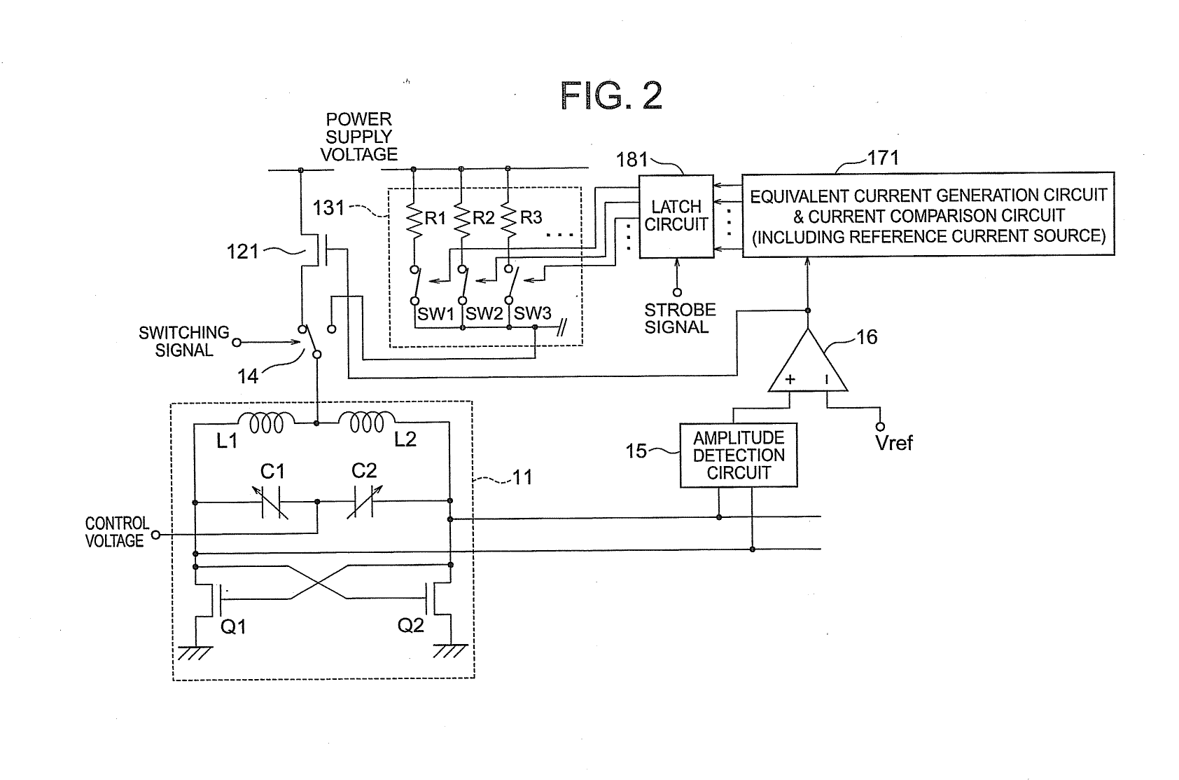

FIG. 2 shows the voltage controlled oscillator shown in FIG. 1 as a more concrete configuration example. In FIG. 2, the same components as those shown in FIG. 1 are designated the same reference numerals. Descriptions thereof are omitted.

In this voltage controlled oscillator, there are used a transistor (pMOS transistor) 121 as the current adjustment element 12, a serial-parallel circuit 131 of resistors and switches as the current adjustment element 13, an equivalent current generation and current comparison circuit 171 as the current estimation circuit 17, and a latch circuit 181 as the control circuit 18, respectively. Further, an LC differential oscillator is used as the oscillation circuit 11. The path between the source and the drain of the transistor 121 is used as a current-adjustable path, and the gate terminal thereof is designated as a current control terminal. The serial-parallel circuit 131 of resistors and switches is a circuit in which a plurality of serial connections of resistors and switches are connected in parallel. Capacitances C1, C2 of the oscillator 11 are variable capacitors in which capacitances vary when the control voltage varies and the bias changes.

Between the transistor 121 and the serial-parallel circuit 131 of resistors and switches, there is a difference as a phase noise source in the case of functioning as a bias current source for the oscillation circuit 11. Specifically, in general, a transistor becomes larger as a phase noise source as compared to resistors. In a state that the transistor 121 is the bias current source for the oscillation circuit 11, quick convergence by feedback is done as already described, and thereby an optimum state of low phase noise with respect to the oscillation amplitude can be obtained. Thereafter, by the serial-parallel circuit 131 of resistors and switches becoming the bias current source for the oscillation circuit 11, a state of low phase noise is further realized also in terms of phase noise source.

The equivalent current generation and current comparison circuit 171 is arranged to generate a current (equivalent current) corresponding to the current allowed to flow in the transistor 121 using a voltage signal for controlling the transistor 121, and further compare the generated current with each of a plurality of current values (reference current values) which differ stepwise from each other to thereby obtain a plurality of comparison results. The plurality of comparison results obtained correspond to current estimation results, which are then led to the latch circuit 181 respectively. The latch circuit 181 latches and stores the plurality of comparison results by the timing when a strobe signal is inputted. The output of the latch circuit 181 is an output having high/low states which are inverted from a lowest order of output to a certain order depending on the magnitude of the current which is actually allowed to flow in the transistor 121.

An output of the latch circuit 181 is led to the serial-parallel circuit 131 of resistors and switches to define opening/closing states of the respective switches therein. Specifically, the switches of the serial-parallel circuit 131 of resistors and switches are turned to on states by the number of inverting high/low states of the output of the latch circuit 181, and as a result, a current substantially close to the current which is allowed to flow by the transistor 121 is allowed to flow into the oscillation circuit 11 by the serial-parallel circuit 131 of resistors and switches. Resistance values of the respective resistors R1, R2, . . . may be determined in advance in consideration of the characteristics from an input of the equivalent current generation and current comparison circuit 171 to a current output allowed to flow by the serial-parallel circuit 131 of resistors and switches according to states of the switches.

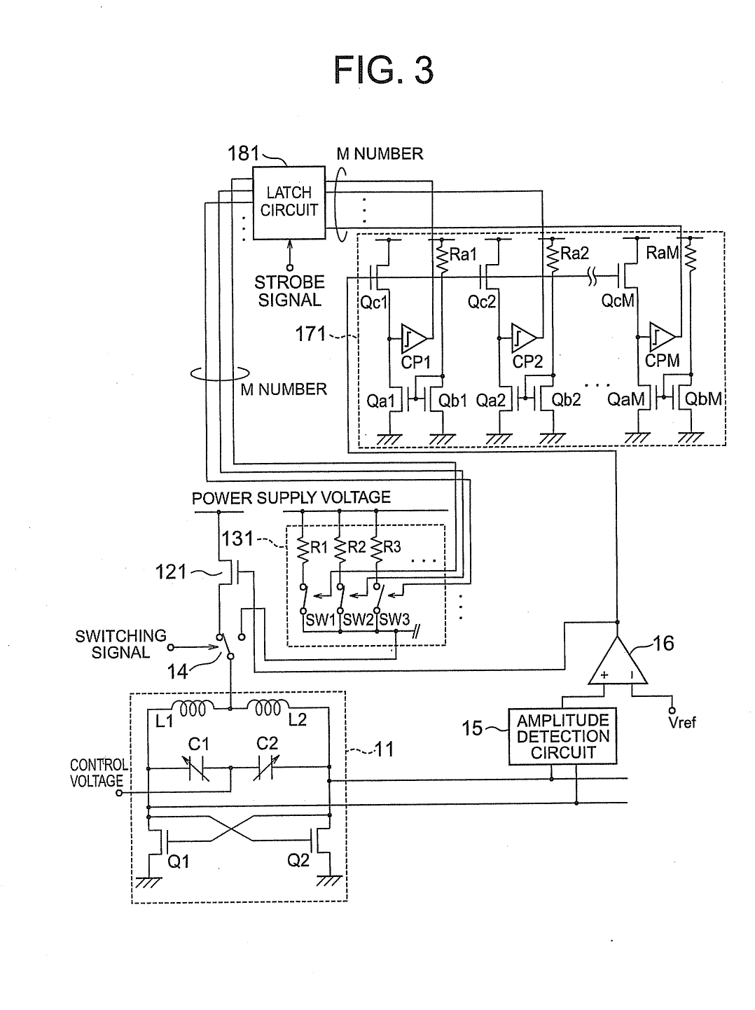

FIG. 3 shows the voltage controlled oscillator shown in FIG. 2 as a further concrete configuration example. In FIG. 3, the same components as those shown in the already explained drawings are designated the same reference numerals. Descriptions thereof are omitted.

This voltage controlled oscillator has, as the equivalent current generation and current comparison circuit 171, current mirror circuits (corresponding to equivalent current generation circuits) constituted of transistors Qcn (n=1 to M) and the transistor 121 respectively, current generation circuits (generation circuits of reference current values) constituted of Ran, Qan, Qbn (n=1 to M) respectively, and comparison circuits (corresponding to current comparison circuits) CPn (n=1 to M) of input current direction determination type.

In this embodiment, by setting the gate width of each of the transistors Qcn (n=1 to M) to 1/a times of that of the transistor 121, the current scale thereof can be reduced to 1/a times as compared to the current in the transistor 121. In this manner, it is possible to reduce consumed power as the equivalent current generation and current comparison circuit 171. Hereinafter, explanation will be given assuming that such a gate width is set.

The transistors Qan (n=1 to M) correspond to the transistors Q1, Q2 of the oscillation circuit 11 in terms of positions to constitute the circuit. Therefore, the gate widths of the transistors Qan (n=1 to M) are set to 2/a times that of the transistors Q1, Q2. The gate widths of the transistors Qbn (n=1 to M) are set to the same as those of the transistors Qan (n=1 to M) to be paired therewith. The resistors Ran (n=1 to M) are each set so that the resistance value thereof is the ratio of a/n according to n. Here, the resistors Ran (n=1 to M) correspond to the respective resistors R1, R2, . . . of the serial-parallel circuit 131 of resistors and switches in terms of positions to constitute the circuit. Therefore, the resistors R1, R2 . . . can be all given the same value R, and the respective resistance values of the resistors Ran (n=1 to M) can be set to R·a/n.

With the configuration of the equivalent current generation and current comparison circuit 171 as above, equivalent currents according to (scale down of) the current which is allowed to flow in the transistor 121 are generated on the respective drains of the transistors Qcn (n=1 to M). Further, reference currents according to (scale down of) currents which should be allowed to flow by the respective resistors R1, R2, . . . of the serial-parallel circuit 131 of resistors and switches are generated in a stepwise manner on the respective drains of the transistors Qan (n=1 to M).

Accordingly, the respective comparison circuits CPn (n=1 to M) of the input current direction determination type, which have input sides connected to connection nodes of the respective drains of Qcn (n=1 to M) and the respective drains of Qan (n=1 to M), provide outputs which include information about what level in the stepwise reference currents the current allowed to flow in the transistor 121 has reached. Specifically, these outputs are outputs having high/low states which are inverted from a lowest order of output to a certain order depending on the magnitude of the current which is actually allowed to flow in the transistor 121. The operation after outputs of the respective comparison circuits CPn (n=1 to M) are led to the latch circuit 181 are as already explained.

In the configuration of the equivalent current generation and current comparison circuit 171 as above,the respective resistance values of the resistors Ran (n=1 to M) can be decided easily depending on resistance values of the respective resistors R1, R2, . . . of the serial-parallel circuit 131 of resistors and switches, and therefore designing can be performed smoothly.

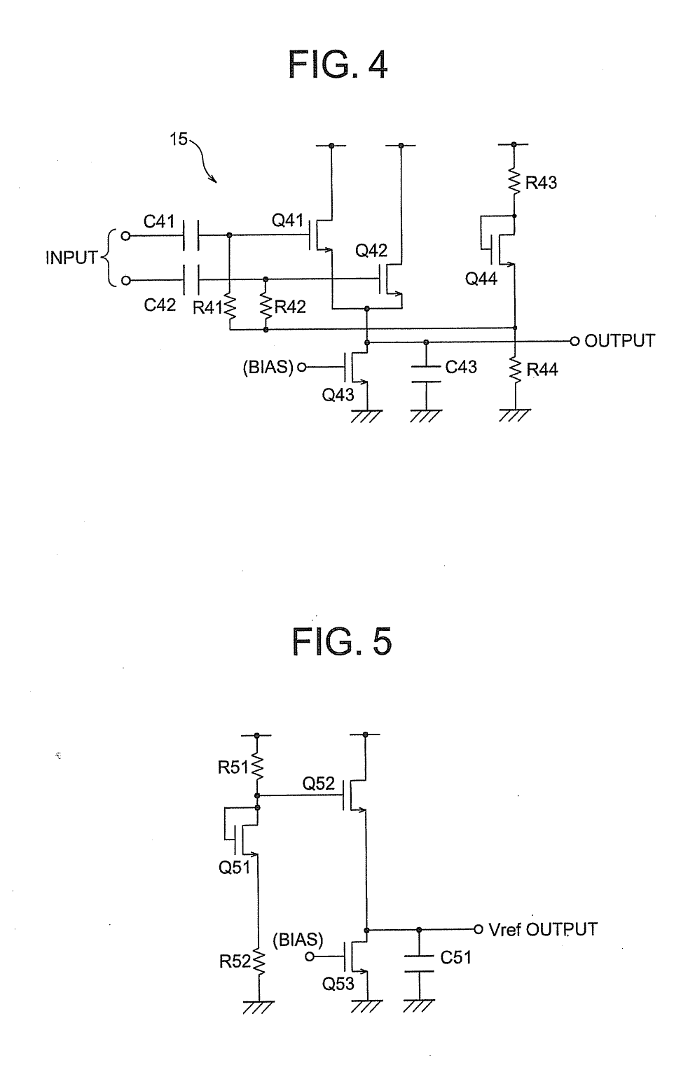

Next, FIG. 4 shows a concrete example of the amplitude detection circuit 15 shown in FIG. 1 to FIG. 3. Further, FIG. 5 shows a concrete example of generating the reference voltage Vref shown in FIG. 1 to FIG. 3.

As shown in FIG. 4, the amplitude detection circuit 15 has two source follower circuits each having Q41, Q42 and supplied with a bias voltage via the resistors R41, R42 from the bias circuit source constituted of R43, Q44, R44. To inputs thereof, outputs of both phases from the oscillation circuit 11 are supplied. After their direct current components are removed in the capacitors C41, C42, the outputs of both phases are inputted to the source follower circuits of Q41, Q42. To Q41, Q42, a bias current is allowed to flow by Q43. A capacitor 43 is connected to the source outputs of Q41, Q42, by which capacitor waveforms are detected (rectified). Detection results thereof are outputs as the amplitude detection circuit. Note that a configuration is also possible such that only one phase is supplied to the input instead of the outputs of both phases of the oscillation circuit 11.

On the other hand, as shown in FIG. 5, for generation of the reference voltage Vref, it is possible to use a source potential of a transistor Q52, which is supplied with a bias voltage from a bias circuit constituted of R51, Q51, R52 (this bias circuit has the same configuration as the bias circuit constituted of R43, Q44, R44). To the transistor Q52, the bias current is allowed to flow by Q53. Q53 has the same gate width as Q43 shown in FIG. 4. C51 is a smoothing capacitor of a source potential of the transistor Q52. The gate width of the transistor Q52 is double of the Q41, Q42 shown in FIG. 4.

According to the amplitude detection circuit 15 shown in FIG. 4 and the generation circuit of the reference voltage Vref shown in FIG. 5, the gate voltage of Q52 is higher by a threshold voltage of the transistor Q51 as compared with gate voltages of Q41, Q42 at a direct current operation point, and hence the difference in output voltages is an amount of the threshold value. Therefore, when these circuits are used in the configuration shown in FIG. 1 to FIG. 3 and allowed to operate by feedback, the state of the feedback is such that the oscillation amplitude (peak-to-peak) of the oscillation circuit 11 becomes the threshold value of the transistor Q51.

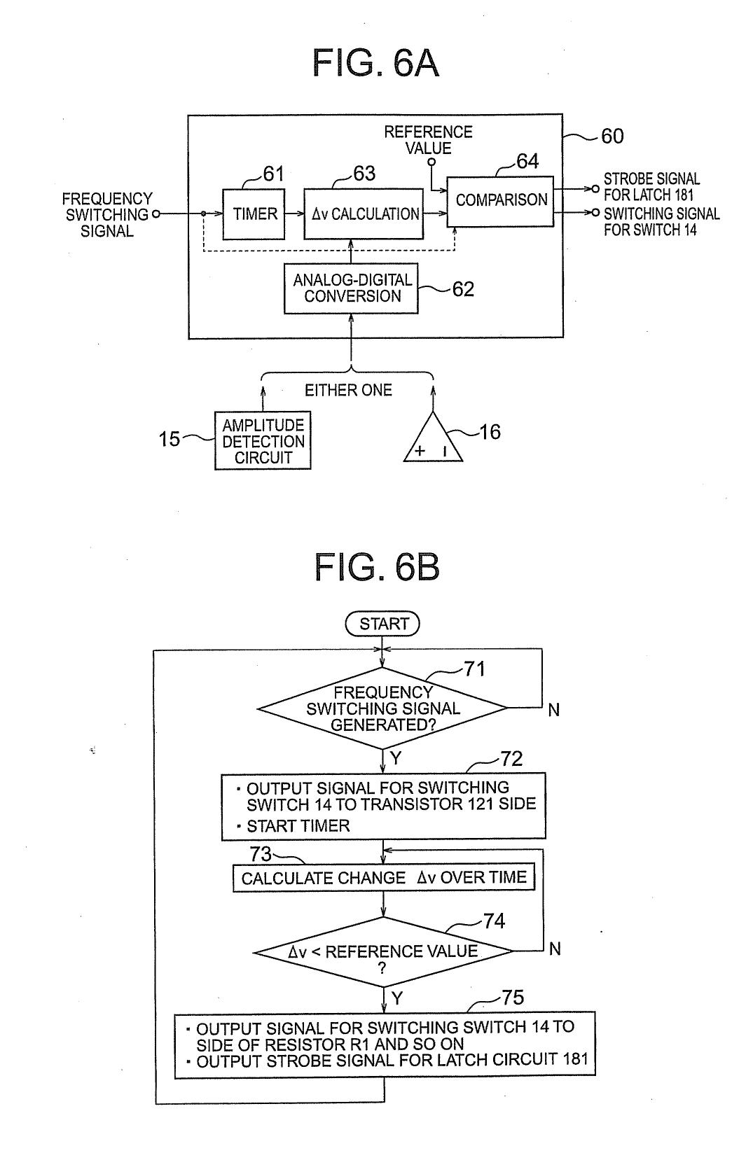

Next, FIG. 6A, FIG. 6B show a control system example generating the switching signal and the strobe signal shown in FIG. 2 and FIG. 3 and the flow of processing thereof, respectively. As shown in FIG. 6A, the control system 60 has a timer 61, an analog-digital conversion unit 62, a Δv calculation unit 63, and a comparison unit 64, as functions thereof. These functions can be realized by, for example, combinations of software and hardware for enabling this software to function.

The timer 61 counts an elapsed time from an instant of generation of a frequency switching signal for switching the band of an oscillation frequency. The analog-digital conversion unit 62 analog-digital converts the output voltage of the amplitude detection circuit 15 or the output voltage of the comparison and amplification circuit 16. The Δv calculation unit calculates a variation amount Δv per predetermined time in the output of the analog-digital conversion unit 62 while the aforementioned elapsed time is counted, in order to monitor variation of the bias voltage in the voltage controlled oscillator equivalently.

The comparison unit 64 generates a switching signal to the circuit 131 side for the switch 14 and a strobe signal for the latch circuit 181 when the variation amount Δv becomes smaller than a reference value. Further, the comparison unit 64 also generates a switching signal to the transistor 121 side for the switch 14 when a frequency switching signal for switching the band of an oscillation frequency is generated.

With reference to FIG. 6B, the flow of processing will be explained. First, if the frequency switching (band switching) signal is not generated, the system waits for generation of this signal (step 71). When the frequency switching signal is generated (Y in step 71), a signal for switching the switch 14 to the transistor 121 side is outputted from the comparison unit 64, and the timer 61 is started (step 72). Then, in the Δv calculation unit 63, the variation Δv per predetermined time is calculated over time from counting by the timer 61 and the output from the analog-digital conversion unit 62 (step 73).

Here, when the variation amount Δv is larger than or equal to the reference value (N in step 74), the calculation of Δv is continued (step 73). When Δv becomes lower than the reference value (Y in step 74), a signal for switching the switch 14 to the side of the resistor R1 and so on (serial-parallel circuit 131 side) is outputted, and the strobe signal for the latch circuit 181 is outputted (step 75). Thereafter, the system returns to the step 71 to perform the processing similarly.

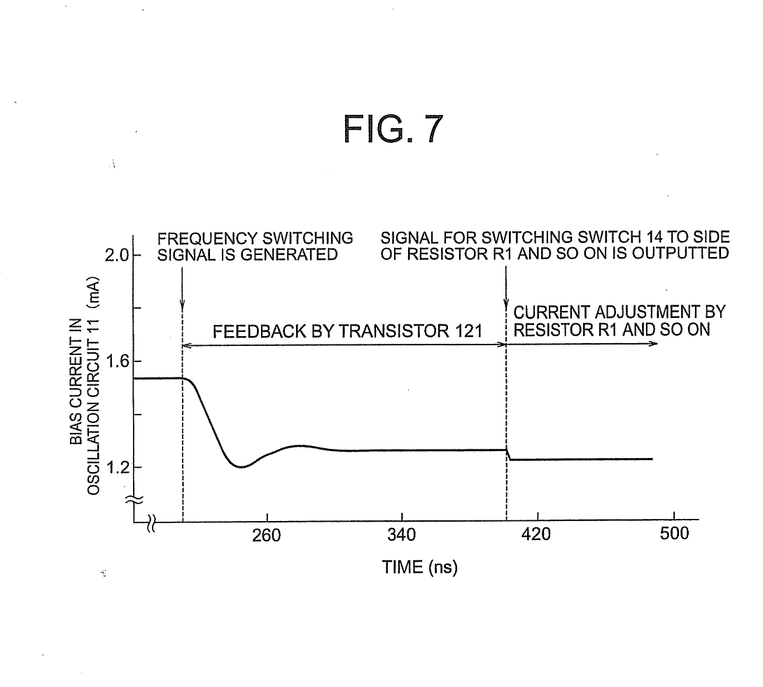

FIG. 7 shows in a time-related manner an example of a state of frequency switching in the voltage controlled oscillator realized by the voltage controlled oscillator shown in FIG. 3 and the system shown in FIG. 6A, FIG. 6B. As shown in FIG. 7, when a frequency switching signal for switching the band of an oscillation frequency is generated, it creates a state that the bias current is allowed to flow in the oscillation circuit 11 by the transistor 121, and at the same time feedback occurs so as to make the bias current which suppresses phase noise. By this function, the bias current quickly converges to a value different from the value before the switching signal is generated.

When sufficient convergence is reached, a state of bias current adjustment by the serial-parallel circuit 131 is created by the switch 14 being switched to the side of the resistor R1 and so on (serial-parallel circuit 131). This state is for allowing the flow of a bias current that is substantially the same as a convergence value of a bias current by the transistor 121, and also is a state that phase noise is suppressed more than with the transistor 121.

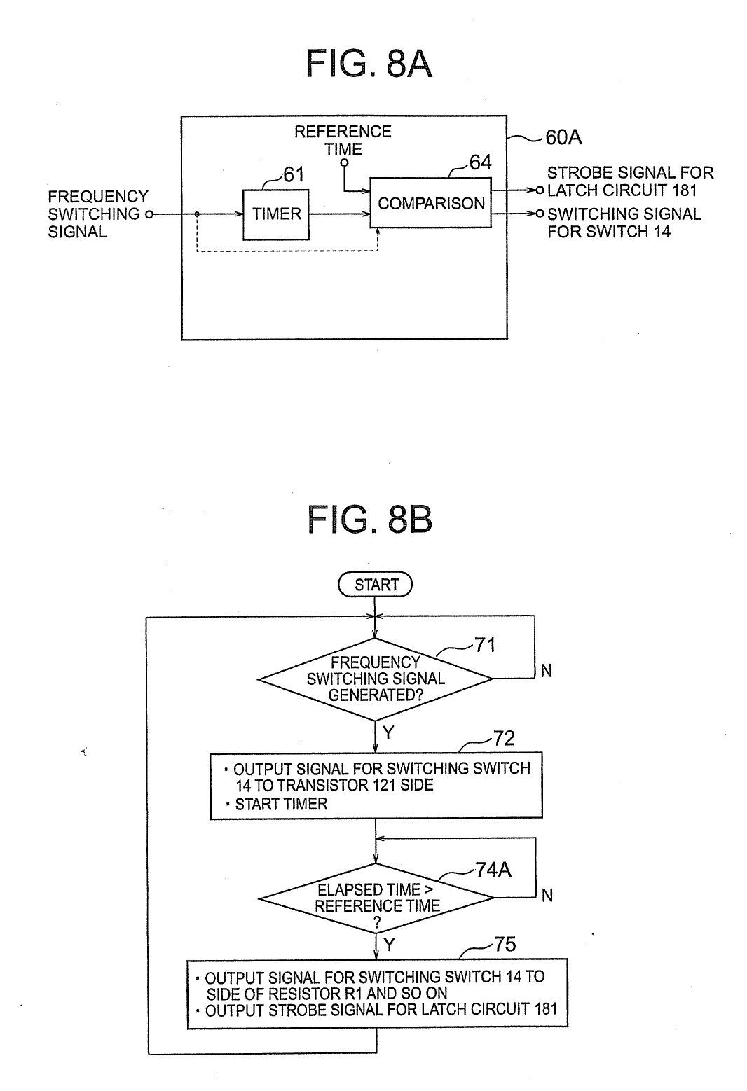

Next, FIG. 8A, FIG. 8B show another control system example generating the switching signal and the strobe signal shown in FIG. 2 and FIG. 3, and the flow of processing thereof. In FIG. 8A, FIG. 8B, the same components as those shown in FIG. 6A, FIG. 6B a redesignated the same reference numerals. Descriptions thereof are omitted. In this example, as simplified processing, calculation of the variation amount Δv is not performed, the switching signal to the serial-parallel circuit 131 side for the switch 14 and the strobe signal for the latch circuit 181 are generated when a time which is determined in advance is elapsed from an instant that the frequency switching signal is generated.

Therefore, as shown in FIG. 8A, the Δv calculation unit 63 does not exist in the control system 60A, and along with this, the analog-digital conversion unit 62 does not exist either. Further, as the processing, as shown in FIG. 8B, the step 73 (step of calculating Δv) shown in FIG. 6B does not exist, and the step 74 of comparing with the reference value is replaced by a step 74A of comparing with a reference time.

Even with such simplification, it is still quite useful practically as long as the convergence process of the feedback by the transistor 121 has small dispersion due to conditions. A load in a system aspect can also be made small.

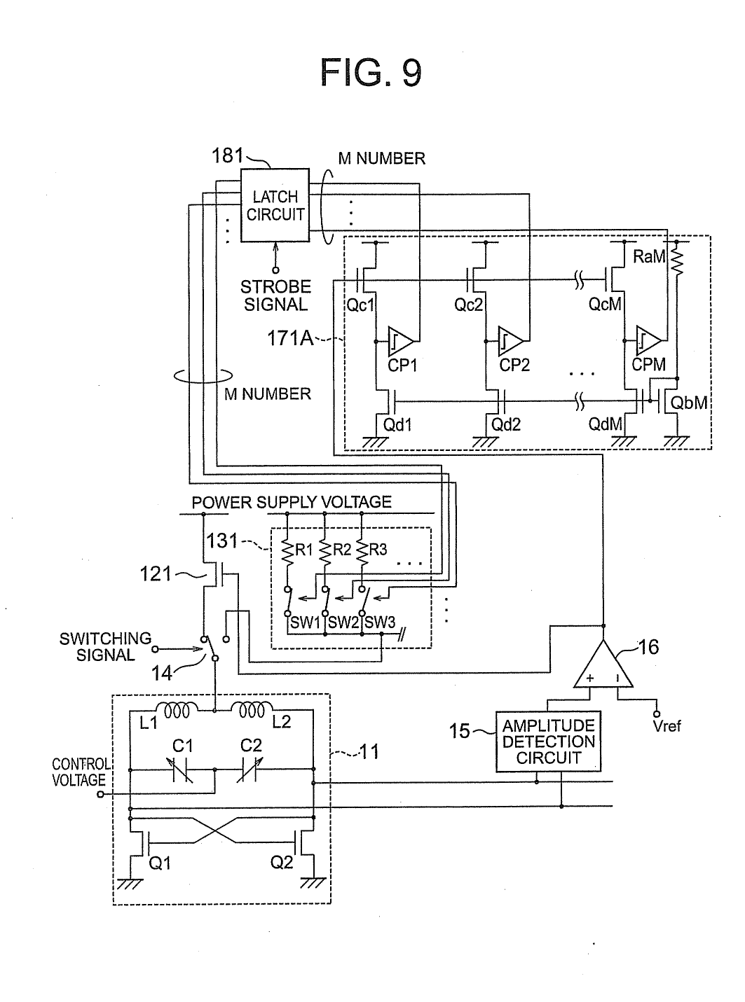

Next, FIG. 9 shows the voltage-controlled oscillator shown in FIG. 2 as another concrete configuration example. In FIG. 9, the same components as those shown in the already explained drawings are designated the same reference numerals. Descriptions thereof are omitted.

In this configuration example, as an equivalent current generation and current comparison circuit 171A, transistors Qdn (n=1 to M) are newly provided as current mirror circuits of a transistor QbM. The transistors Qan (n=1 to M), Qbn (n=1 to M−1), and resistors Ran (n=1 to M−1) do not exist. The respective gate widths of the transistors Qdn (n=1 to M) are set to n/M times the gate width of QbM according to n.

This configuration example is not capable of generating respective reference values for current comparison as accurate as in the configuration example shown in FIG. 3, but is capable of generating the respective reference values with sufficient accuracy in an approximated manner. Complementing this point, it is sufficiently accurate as long as it can be said that, when in the serial-parallel circuit 131 of resistors and switches resistance across both terminals thereof becomes double, the current flowing therein becomes ½.

The embodiments are described above, but it is possible to use a bipolar transistor instead of FET as the transistor constituting the voltage-controlled oscillator. In this case, the gate terminal may correspond to the base terminal, the source terminal to the emitter terminal, and the drain terminal to the collector terminal, respectively. The difference in gate widths can be corresponded by changing an emitter size.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A voltage controlled oscillator, comprising:
a first element capable to pass a first current in a first state, and a second element capable to pass a second current in a second state;
a switching circuit switching between the first state and the second state;
an oscillation circuit configured to generate a first oscillation wave in the first state and a second oscillation wave in the second state;
a current estimation circuit configured to estimate the first current based on a control signal for the first element to control the first current and configured to generate an estimation result; and
a control circuit configured to generate a control signal for the second element using the estimation result and to control the second current through the second element in the second state so that the second current corresponds to the first current.

2. The voltage controlled oscillator according to claim 1, further comprising:
an amplitude detection circuit configured to detect an amplitude of the first oscillation wave in the first state; and
a comparison and amplification circuit configured to amplify a difference between the amplitude and a predetermined value and to generate the control signal for the first element.

3. The voltage controlled oscillator according to claim 1, wherein the first element is a transistor, and the control signal for the first element is supplied to a gate terminal or a base terminal of the transistor.

4. The voltage controlled oscillator according to claim 1,
wherein the second element has a circuit in which a plurality of serial connections of resistors and switches are connected in parallel; and
the control circuit generates the control signal for the second element so as to define opening/closing states of each of the switches.

5. The voltage controlled oscillator according to claim 4,
wherein the current estimation circuit has a plurality of current comparison circuits configured to compare a current according to the current through the first element in the first state with each of a plurality of current values differing stepwise from each other and to generate a plurality of comparison results as the estimation result; and
the control circuit includes a latch circuit configured to generate a stored result corresponding to the plural comparison results, the stored result defining opening/closing states of each of the switches.

6. The voltage controlled oscillator according to claim 1,
wherein the first element is a transistor, the control signal for the first element being supplied to a gate terminal or a base terminal of the transistor;
the second element includes a circuit in which a plurality of serial connections of resistors and switches are connected in parallel;
the current estimation circuit includes a plurality of transistors constituting current mirror circuits respectively with the transistor as the first element, the plural transistors each being allowed to flow a current according to the current through the first element, and a plurality of current comparison circuits configured to compare the current flowing in each of the plural transistors with each of a plurality of current values differing stepwise from each other and to generate a plurality of comparison results as the estimation result; and
the control circuit includes a latch circuit configured to generate a stored result corresponding to the plural comparison results, the stored result defining opening/closing states of each of the switches as the control signal for the second element.

7. The voltage controlled oscillator according to claim 6, wherein, in between the transistor as the first element and the plural transistors constituting the current mirror circuits respectively with the transistor, gate widths or emitter sizes thereof are differentiated from each other so that a current scale is differentiated.

8. The voltage controlled oscillator according to claim 6,
wherein the current comparison circuit includes a plurality of resistors having resistance values differing stepwise from each other; and
the plural current values of the current comparison circuit correspond to values of currents allowed to flow in the plural resistors, respectively.

9. The voltage controlled oscillator according to claim 6,
wherein the current comparison circuit includes a plurality of transistors having gate widths or emitters whose sizes differ stepwise from each other; and
the plural current values in the current comparison circuit correspond to values of currents allowed to flow in the plural transistors having the gate widths or emitters of the sizes, respectively.

10. A bias device for a voltage controlled oscillator, comprising:
a current estimation circuit configured to estimate, for an oscillation circuit generating an oscillation wave in a state that a current passing through a first element is inputted, the current passing through the first element and to generate an estimation result; and
a control circuit configured to control a second element, when an oscillation wave is generated in a state that a current passing through the second element instead of the first element is inputted to the oscillation circuit, so as to designate a current according to the estimation result as the current passing through the second element.

11. A bias adjustment program for a voltage-controlled oscillator, the program comprising instructions to cause a processor to execute:
counting an elapsed time from an instant of generation of a frequency switching signal;
monitoring changes of a bias current in a voltage controlled oscillator equivalently while the elapsed time is counted;
determining whether or not changes of the bias current per predetermined time fall within a predetermined range based on the counting; and
outputting to the voltage controlled oscillator a signal for switching an element adjusting the bias current when the changes of the bias current per the predetermined time fall within the predetermined range.

12. A bias adjustment program for a voltage controlled oscillator, the program comprising instructions to cause a processor to execute:
counting an elapsed time from an instant of generation of a frequency switching signal; and
outputting, when the elapsed time reaches a predetermined time, to a voltage controlled oscillator a signal for switching an element adjusting a bias current of the voltage controlled oscillator.
